(19) United States
(12) Patent Application Publication
(10) Pub. No.: US 2025/0203814 A1
(43) Pub. Date: Jun. 19, 2025

(54) MAINTENANCE CLEANSING SYSTEM FOR LIQUID-COOLED RACK-MOUNTED PROCESSING ASSEMBLIES

(71) Applicant: OVH, Roubaix (FR)

(72) Inventors: Ali CHEHADE, Moncheaux (FR); Gregory Francis Louis BAUCHART, Wattrelos (FR); Mohamad HNAYNO, Roubaix (FR)

(21) Appl. No.: 18/979,571

(22) Filed: Dec. 12, 2024

(30) Foreign Application Priority Data
Dec. 15, 2023 (EP) 23307234.7

(51) Int. Cl. H05K 7/20; C02F 1/00; C02F 1/42; C02F 1/44; C02F 1/66; C02F 103/02

(52) U.S. Cl. CPC H05K 7/20272; C02F 1/008; C02F 1/42; C02F 1/44; C02F 1/66; H05K 7/20781; H05K 7/20836; C02F 2103/023; C02F 2303/08

(57) ABSTRACT

A cleansing system and method for liquid-cooled rack-mounted processing assemblies are presented that incorporate a cleansing unit comprising a first liquid comprising an acidic detergent coupled a first fluid control structure, a second liquid comprising softened water fluidly-coupled a second fluid control structure, a third liquid comprising treated osmosed water fluidly-coupled a third fluid control structure, and a control module operably-coupled to the control structures and configured to select one of the first, second, or third liquids and define corresponding first, second, and third operational cleansing cycles and duration times. A forward fluid coupling section supplies the selected liquid to the processing assemblies and a return fluid coupling section receives the returned liquid from the processing assemblies for each of the defined operational cleansing cycles. In the event that liquid quality levels from the returning processing assemblies are unsatisfactory, a fourth operational cycle is defined and executed.

### CROSS REFERENCE

The present application claims priority to European Patent Appl. No. 23307234.7, filed Dec. 15, 2023 entitled “A MAINTENANCE CLEANSING SYSTEM FOR LIQUID-COOLED RACK-MOUNTED PROCESSING ASSEMBLIES”, the entirety of which is incorporated herein by reference.

### FIELD

The present technology generally relates to the field of datacenter liquid cooling arrangements and, in particular, to the cleansing of existing liquids servicing the liquid cooling needs of rack-mounted processing assemblies.

### BACKGROUND

Datacenters as well as many computer processing facilities house multitudes rack-mounted electronic processing components. In operation, such electronic processing components generate a substantial amount of heat that must be dissipated in order avoid electronic component failures and ensure continued efficient processing operations.

To this end, various liquid cooling measures have been implemented to facilitate the dissipation of heat generated by the electronic processing components. One such measure, is the use of an immersion liquid cooling technique, in which electronic components are fully submerged in a rack casing containing a non-conductive cooling liquid, such as, for example, a dielectric cooling liquid. The immersion of the electronic components within the dielectric cooling liquid achieves adequate thermal contact between the electronic components to dissipate a fair amount of generated heat.

However, there are certain electronic components, such as, for example, high-performance processing units that tend to generate more heat than other electronic components (e.g., memory boards) and dielectric liquid immersion measures may not serve to sufficiently cool such high heat-generating components. To address the cooling of these high heat-generating components, direct liquid cooling block measures have been implemented, in which liquid cooling blocks having internal channels to circulate cool water therethrough are disposed in direct thermal contact with the high heat-generating components.

The Inventors of the instant application have identified evidence of undesirable contaminants that develop, over time, due to the circulation of channelized water throughout the liquid cooling blocks and corresponding distribution channels and coupling elements. Such evidence of undesirable contaminants includes the buildup of mineral deposits, corrosion, algae, bacteria, etc. that affect the quality of the water as well as the efficient flow of the channelized water.

Hence, there is an interest in eliminating the buildup of such undesirable contaminants as well as reducing reoccurrences of the same in direct liquid cooling block implementations.

The subject matter discussed in the background section should not be assumed to be prior art merely as a result of its mention in the background section. Similarly, a problem mentioned in the background section or associated with the subject matter of the background section should not be assumed to have been previously recognized in the prior art. The subject matter in the background section merely represents different approaches.

### SUMMARY

Embodiments of the present technology have been developed based on certain drawbacks associated with the buildup of various contaminants within mineral deposits, corrosion, algae, bacteria, etc. techniques and implementations.

In one aspect of the inventive concepts, the present technology provides a maintenance cleansing system for a liquid-cooled rack-mounted data processing assembly comprising a cleansing unit that incorporates a first tank containing a volume of a first liquid comprising a detergent having an acidic ph level and fluidly-coupled a first fluid control structure, a second tank containing a volume of a second liquid comprising softened or pure water and fluidly-coupled a second fluid control structure, and a third tank containing a volume of a third liquid comprising treated osmosed water with corrosion inhibitors having a basic ph level and fluidly-coupled a third fluid control structure. The system further comprises a control module operably-coupled to the first, second, and third fluid control structures and configured to select one of the first, second, or third liquids and define a corresponding first, second, and third operational cleansing cycle and cycle duration time, a forward fluid coupling section configured to supply the selected liquid to the rack-mounted processing assemblies, and a return fluid coupling section configured to receive the selected liquid from the rack-mounted processing assemblies, a rack unit fluid inlet configured to receive the selected fluid from the forward fluid coupling section and distribute the selected liquid throughout each of the rack-mounted processing assemblies for a corresponding cleansing cycle, and a rack unit fluid outlet configured to receive the distributed selected liquid from each of the rack-mounted processing assemblies, during the corresponding cleansing cycle, and return the distributed selected liquid back to the respective tank.

A feature of the maintenance cleansing system includes a fourth tank containing a volume of a fourth liquid comprising a volume of treated osmosed water with corrosion inhibitors having a basic ph level and fluidly-coupled to a fourth fluid control structure for selection by the control module to establish a corresponding fourth cleansing cycle and cycle duration time.

Another feature of the maintenance cleansing system provides that each of the first, second, third, and fourth fluid control structures comprises a respective supply liquid channel incorporating at least one pump and at least one solenoid valve for providing proper pressure and flow of the selected liquid into the datacenter rack unit.

An additional feature of the maintenance cleansing system provides that each of the first, second, third, and fourth fluid control structures comprises a respective return liquid channel incorporating at least one filter and at least one heat exchanger for recleaning and recooling the returned selected liquid.

Another feature of the maintenance cleansing system is that the cleansing unit performs the first, second, third, and fourth cleansing cycles while the data processing assemblies remain in operation.

Also, a feature of the maintenance cleansing system is that the cleansing unit further comprises a wheel assembly for transportability throughout a datacenter.

In another aspect of the inventive concepts, the present technology provides a maintenance cleansing process for a liquid-cooled rack-mounted data processing assembly comprising defining an operational cleansing cycle and duration time for a first liquid comprising a detergent having an acidic ph level, a second liquid comprising water softening agents, and a third cleansing liquid comprising treated osmosed water having a basic ph level; selecting the first liquid and executing the first operational cleansing cycle for the first duration time to inject and circulate the flow of the first liquid throughout the processing assemblies; upon termination of the first operational cleansing cycle, selecting the second liquid and executing the second operational cleansing cycle for the second duration time to inject and circulate the flow of the second liquid throughout the processing assemblies; and upon termination of the second operational cleansing cycle, selecting the third liquid and executing the third operational cleansing cycle for the third duration time to inject and circulate the flow of the third liquid throughout the processing assemblies.

An additional feature of the maintenance cleansing process comprises defining an operational cleansing cycle and duration time for a fourth liquid comprising treated osmosed water having a basic ph level in which, upon detecting remaining contaminants and/or significant drop in ph levels, selecting the fourth liquid and executing the fourth operational cleansing cycle for the fourth duration time to inject and circulate the flow of the fourth liquid throughout the processing assemblies.

In the context of the present specification, unless expressly provided otherwise, a computer system may refer, but is not limited to, an “electronic device”, an “operation system”, a “system”, a “computer-based system”, a “controller unit”, a “monitoring device”, a “control device” and/or any combination thereof appropriate to the relevant task described.

In the context of the present specification, unless expressly provided otherwise, the expression “computer-readable medium” and “memory” are intended to include media of any nature and kind whatsoever, non-limiting examples of which include RAM, ROM, disks (CD-ROMs, DVDs, floppy disks, hard disk drives, etc.), USB keys, flash memory cards, solid state-drives, and tape drives. Still in the context of the present specification, “a” computer-readable medium and “the” computer-readable medium should not be construed as being the same computer-readable medium. To the contrary, and whenever appropriate, “a” computer-readable medium and “the” computer-readable medium may also be construed as a first computer-readable medium and a second computer-readable medium.

In the context of the present specification, unless expressly provided otherwise, the words “first”, “second”, “third”, etc. have been used as adjectives only for the purpose of allowing for distinction between the nouns that they modify from one another, and not for the purpose of describing any particular relationship between those nouns.

Implementations of the present technology each have at least one of the above-mentioned objects and/or aspects, but do not necessarily have all of them. It should be understood that some aspects of the present technology that have resulted from attempting to attain the above-mentioned object may not satisfy this object and/or may satisfy other objects not specifically recited herein.

Additional and/or alternative features, aspects and advantages of implementations of the present technology will become apparent from the following description, the accompanying drawings and the appended claims.

### BRIEF DESCRIPTION OF THE DRAWINGS

For a better understanding of the present technology, as well as other aspects and further features thereof, reference is made to the following description which is to be used in conjunction with the accompanying drawings, where:

FIG. 1 illustrates a high-level functional block diagram of a maintenance cleansing system for a liquid-cooled rack-mounted data processing assembly, in accordance with the nonlimiting embodiments of the present technology;

FIG. 2 illustrates a high-level block diagram for the operational configuration of fluid control structures, in accordance with the nonlimiting embodiments of the present technology;

FIG. 3 illustrates a high-level flow diagram for maintenance cleansing process of a liquid-cooled rack-mounted data processing assembly, in accordance with the nonlimiting embodiments of the present technology; and

FIG. 4 depicts a schematic block diagram of a control module, in accordance with the nonlimiting embodiments of the present technology.

It should be appreciated that, unless otherwise explicitly specified herein, the drawings are not to scale.

### DETAILED DESCRIPTION

The examples and conditional language recited herein are principally intended to aid the reader in understanding the principles of the present technology and not to limit its scope to such specifically recited examples and conditions. It will be appreciated that those skilled in the art may devise various arrangements that, although not explicitly described or shown herein, nonetheless embody the principles of the present technology.

Furthermore, as an aid to understanding, the following description may describe relatively simplified implementations of the present technology. As persons skilled in the art would understand, various implementations of the present technology may be of a greater complexity.

In some cases, what are believed to be helpful examples of modifications to the present technology may also be set forth. This is done merely as an aid to understanding, and, again, not to define the scope or set forth the bounds of the present technology. These modifications are not an exhaustive list, and a person skilled in the art may make other modifications while nonetheless remaining within the scope of the present technology. Further, where no examples of modifications have been set forth, it should not be interpreted that no modifications are possible and/or that what is described is the sole manner of implementing that element of the present technology.

Moreover, all statements herein reciting principles, aspects, and implementations of the present technology, as well as specific examples thereof, are intended to encompass both structural and functional equivalents thereof, whether they are currently known or developed in the future. Thus, for example, it will be appreciated by those skilled in the art that any block diagrams herein represent conceptual views of illustrative circuitry embodying the principles of the present technology. Similarly, it will be appreciated that any flowcharts, flow diagrams, state transition diagrams, pseudo-code, and the like represent various processes that may be substantially represented in non-transitory computer-readable media and so executed by a computer or processor, whether or not such computer or processor is explicitly shown.

The functions of the various elements shown in the FIGs. including any functional block labeled as a “processor”, may be provided through the use of dedicated hardware as well as hardware capable of executing software in association with appropriate software. When provided by a processor, the functions may be provided by a single dedicated processor, by a single shared processor, or by a plurality of individual processors, some of which may be shared. In some embodiments of the present technology, the processor may be a general-purpose processor, such as a central processing unit (CPU) or a processor dedicated to a specific purpose, such as a digital signal processor (DSP). Moreover, explicit use of the term a “processor” should not be construed to refer exclusively to hardware capable of executing software, and may implicitly include, without limitation, application specific integrated circuit (ASIC), field programmable gate array (FPGA), read-only memory (ROM) for storing software, random access memory (RAM), and non-volatile storage. Other hardware, conventional and/or custom, may also be included.

Software modules, or simply modules which are implied to be software, may be represented herein as any combination of flowchart elements or other elements indicating performance of process steps and/or textual description. Such modules may be executed by hardware that is expressly or implicitly shown. Moreover, it should be understood that module may include for example, but without being limitative, computer program logic, computer program instructions, software, stack, firmware, hardware circuitry or a combination thereof which provides the required capabilities.

Given this fundamental understanding, the disclosed embodiments are directed to a cleansing system for liquid-cooled rack-mounted processing assemblies that is configured to eliminate the buildup of undesirable contaminants as well as reduce reoccurrences of the same in direct liquid cooling block implementations. The cleansing system is capable of executing cleaning cycles while processing assemblies are in operation with no downtime.

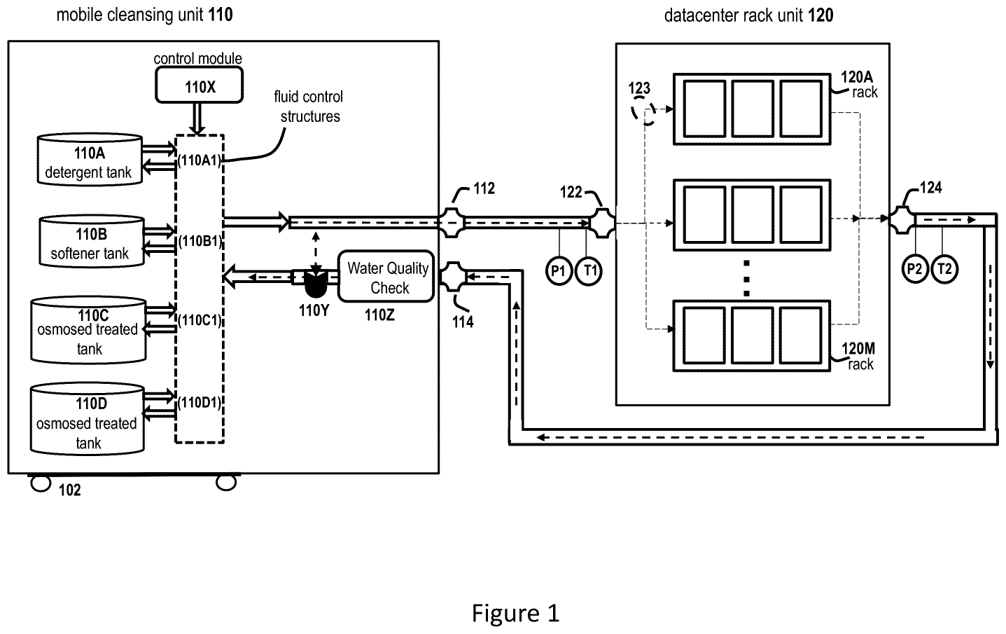

FIG. 1 illustrates a illustrates a high-level functional block diagram of a maintenance cleansing system 100 for a liquid-cooled rack-mounted data processing assembly, in accordance with the nonlimiting embodiments of the present technology. As depicted, maintenance cleansing system 100 generally comprises a cleansing unit 110 that is in fluid communication and contact with a datacenter rack unit 120.

Starting with the datacenter rack unit 120, the rack unit 120 may house a rack or a plurality of racks 120A-120M, in which each rack comprises one or more rack-mounted data processing assemblies. Each of the rack-mounted data processing assemblies contains heat-generating processing components (not shown) such as servers which are cooled by liquid cooling blocks (not shown), also called “water blocks”, that are arranged to be in direct thermal contact with the heat-generating components.

In turn, each of the liquid cooling blocks employs internal channels that are fluidly-coupled to a rack liquid cooling loop 123 which conveys cooling liquid (e.g. water) and circulates the channelized cool cooling liquid internally throughout the liquid cooling blocks as well as conveys the warm cooling liquid heated by the heat-generating components for further cooling processing. The server rack liquid cooling loop 123 may be constructed from flexible materials (e.g., rubber, plastic, etc.), rigid materials (e.g., metal, PVC piping, etc.), or any combination of thereof capable of securely conveying and circulating cool cooling liquid.

The datacenter rack unit 120 also implements a rack unit liquid inlet 122 and a rack unit liquid outlet 124. The liquid inlet 122 is fluidly coupled to an input side of the server rack liquid cooling loop 123 to supply cool cooling liquid to the liquid cooling blocks and incorporates a pressure sensor P1 and a temperature sensor T1 to monitor the pressure and temperature values of the liquid ingressing into the rack unit 120 via the rack liquid cooling loop 123. The pressure sensor P1 and a temperature sensor T1 respectively provide pressure and temperature values to determine whether that the proper liquid flow pressure and temperature entering the rack unit 120 are capable of maintaining the continued operations of the data processing assemblies in the racks 120A-120M.

The rack unit liquid outlet 124 is fluidly-coupled to an output side of the liquid cooling loop 123 to receive warm cooling liquid from the liquid cooling blocks that are heated due to the heat-generating components and incorporates a pressure sensor P2 and a temperature sensor

T2 to monitor the pressure and temperature values of the liquid egressing from the rack unit 120 via the rack liquid cooling loop 123. The pressure sensor P2 and a temperature sensor T2 respectively provide pressure and temperature values to determine whether that the proper liquid flow pressure and temperature exiting the rack unit 120 are maintaining the continued operations of the data processing assemblies of the racks 120A-120M.

For cleansing purposes, the present technology exploits the infrastructure provided by the liquid inlet 122, liquid cooling loop 123, and liquid outlet 124 to distribute various cleansing liquids, in accordance with specified cleansing cycles, from the cleansing unit 110 throughout the liquid cooling loop 123 and the return of the cleansing liquids containing contaminant residues (i.e., “dirty liquids”) back to cleansing unit 110.

Turning to the cleansing unit 110 of FIG. 1, the cleansing unit 110 comprises a plurality of liquid tanks 110A-110D, a controller, or “control module” 110X, a fluid control structure 110A1-110D1 corresponding to each of the liquid tanks, a forward fluid coupling section 112, a return fluid coupling section 114, a water quality check (WQC) bench 110Z, and a motorized three-way valve 110Y.

Each of the plurality of liquid tanks 110A-110D contains a volume of a liquid having specific cleansing/treatment properties. In certain embodiments, a first tank 110A may contain a first volume of liquid including a detergent having an acidic ph level. The detergent may contain citric-based additive agents for the effective and environmentally-friendly removal of a variety of mineral deposits and contaminants. A second tank 110B may contain a second volume of liquid comprising water softening additive agents or pure water to ionically remove mineral deposits. A third tank 110C may contain a third volume of liquid comprising osmosed water with corrosion inhibitors having a basic ph level to provide a cooling fluid substantially free of contaminants.

In certain implementations, the mobile cleansing unit 110 may include a fourth tank 110D that contains a fourth volume of liquid also including osmosed water with corrosion inhibitors having a basic ph level to provide a cooling fluid free of contaminants.

As noted above, the mobile cleansing unit 110 further comprises a forward fluid coupling section 112, a return fluid coupling section 114, a water quality check (WQC) bench 110Z, and a motorized three-way valve 110Y. The forward fluid coupling section 112 operates to fluidly convey the liquid from a selected tank 110A-110D to the rack unit 120 and the return fluid coupling section 114 operates to return the fluid distributed throughout the rack unit 120 back to the mobile cleansing unit 110.

The WQC bench 110Z is connected to the return fluid coupling section 114 comprising a pump (not shown) and water quality sensors (not shown) to measure certain liquid quality levels, such as, for example, pH level, electrical conductivity, aluminum, copper, and zinc content, aerobic microorganism content, etc. of the existing liquid circulating within the rack unit 120. In certain implementations satisfactory liquid quality levels may encompass a pH balance of approximately between 8 and 10, an electrical conductivity of approximately less than 170 (μS/cm), an aluminum, copper, and zinc content of approximately less than 0.6 ppm and an aerobic microorganism content of approximately less than 1000 cfu/ml.

With this WQC 110Z configuration, when liquid from the rack unit 120 is connected to the mobile cleansing unit 110 via return fluid coupling section 114, WQC 110Z may perform a pretest to determine if the returned liquid needs cleaning based on the quality levels measured by the sensors. If so, WQC 110Z directs the motorized three-way valve 110Y to open the fluid control structure 110A1-110D1 (discussed below) of a respective liquid tank 110A-110D. Moreover, at the end of a predetermined cleansing cycle duration time t, the returned liquid is tested again by WQC 110Z to determine whether the quality levels are satisfactory or whether cleansing cycles should be repeated for one or more stages.

As shown in FIG. 1, each of the liquid tanks 110A-110D is operably connected to a respective fluid control structure 110A1-110D1. As will be described in greater detail below, the fluid control structures 110A1-110D1 function to actuate and control the circulation of the liquids based on a corresponding cleansing operational cycle and duration time while still maintaining the data processing assemblies 120A-120M operational throughout the cleansing process.

The control module 110X is configured to establish a corresponding cleansing operational cycle and cycle duration time for each of the liquids based on the cleansing/purifying properties of the individual liquids. The control module 110X is further configured to be communicatively-coupled to each of the fluid control structures 110A1-110D1 to provide instructions regarding the actuation and control of the circulation of liquids during respective operational cleansing cycles and duration times.

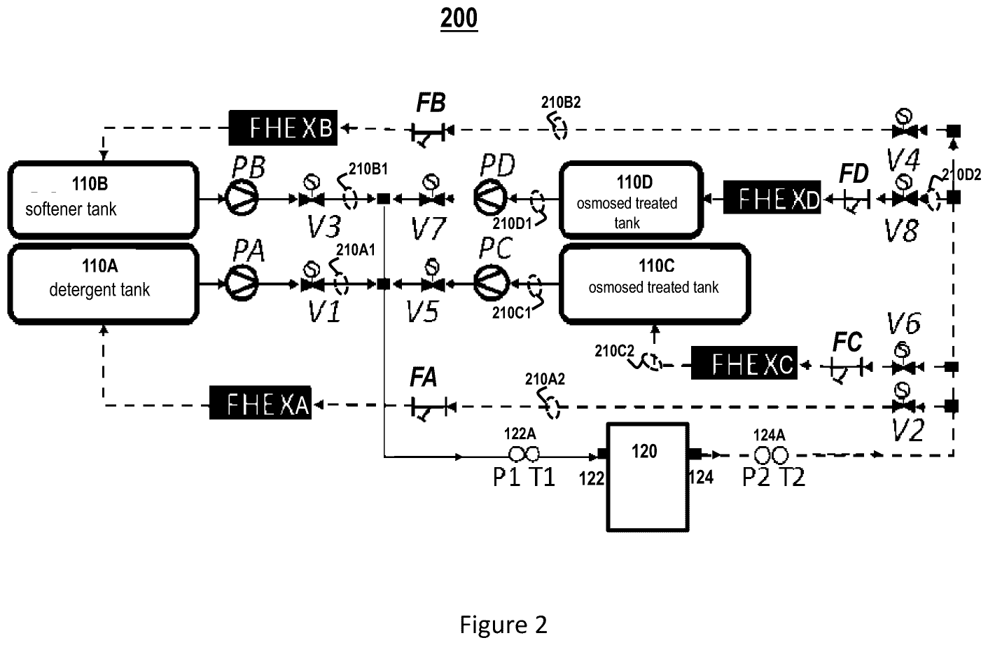

FIG. 2 depicts a high-level block diagram for an operational configuration 200 of fluid control structures 110A1-110D1, in accordance with the nonlimiting embodiments of the present technology. As shown, configuration 200 depicts the fluid interconnection between each of the liquid tanks 110A-110D, and the corresponding structural control/monitoring components, and the liquid circulation channels servicing the supply of liquids from the liquid tanks 110A-110D to the data processing assemblies 120A-120M of datacenter rack unit 120 and the return of the contaminated liquids, i.e., “dirty liquids,” from the rack unit 120 back to the respective tanks 110A-110D.

Specifically, the fluid control structure 110A1 corresponding to the first liquid tank 110A includes a first supply liquid channel 210A1 for forwarding the first liquid containing acidic detergent to the datacenter rack unit 120 and a first return liquid channel 210A2 for receiving the “dirty” detergent liquid from the datacenter rack unit 120. As shown, the first supply liquid channel 210A1 comprises pump PA to provide a proper pressure for the first liquid flow into the datacenter rack unit 120 and a solenoid valve V1 that operates to enable the forward injection flow of the first liquid. The actuation, control, and duration time of pump PA and valve V1 for forwarding the injection flow of the first liquid are mandated by the first liquid cleansing operational cycle and duration time established by the control module 110X.

The first return liquid channel 210A2 includes a solenoid valve V2, a filter FA, and an air-to-liquid heat exchanger FHEXA. The valve V2 enables the return flow of the first “dirty” detergent liquid from the datacenter rack unit 120, the filter FA functions to re-cleanse the “dirty” detergent liquid by substantially removing the contaminants therein, and the air-to-liquid heat exchanger FHEXA functions to re-cool the re-cleansed detergent liquid and return back to first liquid detergent tank 110A for recirculation until the corresponding cleansing cycle duration time has lapsed.

The remaining fluid control structures 110B1-110D1 of the corresponding the liquid tanks 110A-110D are similarly structured. That is, the fluid control structure 110B1 corresponding to the second liquid tank 110B includes a second supply liquid channel 210B1 for forwardly injecting the flow of the second liquid containing water softener agents to the datacenter rack unit 120 and a second return liquid channel 210B2 for receiving the second “dirty liquid” from the datacenter rack unit 120.

The second supply liquid channel 210B1 includes a pump PB to provide a proper pressure for the second liquid flow into the datacenter rack unit 120 and a solenoid valve V3 to enable the forward injection flow of the second water softening liquid. The second return liquid channel 210B2 comprises a solenoid valve V4, a filter FB, and an air-to-liquid heat exchanger FHEXB. The valve V4 enables the return flow of the second “dirty” water softening liquid from the datacenter rack unit 120, filter FB functions to re-cleanse the “dirty” water softening liquid by substantially removing the contaminants therein, and the air-to-liquid heat exchanger FHEXB functions to re-cool the re-cleansed water softening liquid and return back to second liquid detergent tank 110B for recirculation until the corresponding cleansing cycle duration time has lapsed. The actuation, control, and duration time of pump PB, valves V3, V4, and the air-to-liquid heat exchanger FHEXB is mandated by the second liquid cleansing operational cycle and duration time established by the control module 110X.

The fluid control structure 110C1 corresponding to the third liquid tank 110C comprises a third supply liquid channel 210C1 for forwardly injecting the third liquid containing osmosed water treated with additives to the datacenter rack unit 120 and a third return liquid channel 210C2 for receiving the third “dirty” osmosed treated water from the datacenter rack unit 120.

The third supply liquid channel 210C1 includes pump PC to provide a proper pressure for the third liquid flow into the datacenter rack unit 120 and a solenoid valve V5 to enable the forward injection flow of the third liquid into the datacenter rack unit 120. The third return liquid channel 210C2 includes a solenoid valve V6, a filter FC, and an air-to-liquid heat exchanger FHEXC. The filter FC functions to re-cleanse the “dirty” osmosed treated water by substantially removing the contaminants therein, and the air-to-liquid heat exchanger FHEXC functions to re-cool the re-cleansed treated water and return back to third liquid detergent tank 110B for recirculation until the corresponding cleansing cycle duration time has lapsed.

The actuation, control, and duration time of pump PC, valves V5, V6, and the air-to-liquid heat exchanger FHEXC is mandated by the third liquid cleansing operational cycle and duration time established by the control module 110X.

In like fashion, the fluid control structure 110D1 corresponding to the fourth liquid tank 110D comprises a fourth supply liquid channel 210D1 for forwardly injecting the fourth liquid containing osmosed water treated with additives to the datacenter rack unit 120 and a fourth return liquid channel 210D2 for receiving the fourth “dirty” osmosed treated water from the datacenter rack unit 120.

The fourth supply liquid channel 210D1 comprises pump PD to provide a proper pressure for the third liquid flow into the datacenter rack unit 120 and a solenoid valve V7 to enable the forward injection flow of the fourth liquid into the datacenter rack unit 120. The fourth return liquid channel 210D2 comprises a solenoid valve V8, a filter FD, and an air-to-liquid heat exchanger FHEXD. The filter FD functions to re-cleanse the “dirty” osmosed treated water by substantially removing the contaminants therein, and the air-to-liquid heat exchanger FHEXD functions to re-cool the re-cleansed treated water and return back to fourth liquid detergent tank 110B for recirculation until the corresponding cleansing cycle duration time has lapsed.

The actuation, control, and duration time of the actuation of the pump PD, the valves V7, V8, and the air-to-liquid heat exchanger FHEXD are mandated by the fourth liquid cleansing operational cycle and duration time established by the control module 110X.

Given the disclosed configuration, each of the fluid control structures 110A1-110D1 respectively connected to the liquid tanks 110A-110D are designed to inject the appropriate cleansing liquids to the data processing assemblies 120A-120M of datacenter rack unit 120 and return the “dirty” liquids back to the respective liquid tanks 110A-110D, in accordance with the specific operational cleansing cycles and cycle duration times established by control module 110X. As such, the cleansing cycles are capable of being executed while maintaining the data processing assemblies 120A-120M operational throughout the cleansing process.

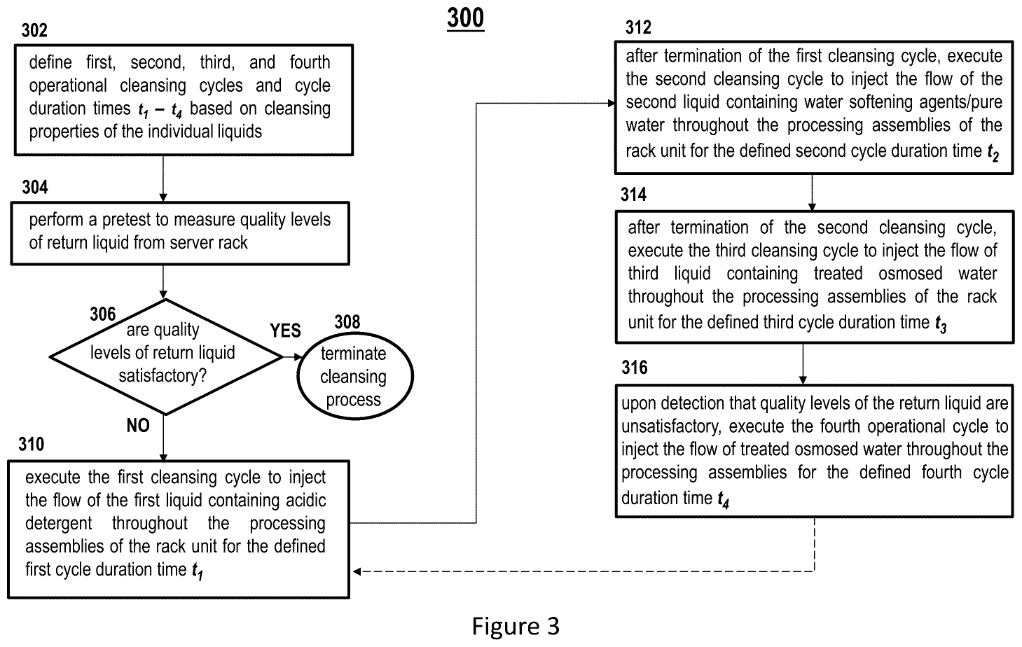

FIG. 3 illustrates a high-level flow diagram for a maintenance cleansing process 300, in accordance with the nonlimiting implementations of the present technology. In the disclosed implementation, maintenance cleansing process 300 or portions thereof are referenced as being executed by control module 110X for tractability purposes. However, the exact entity or entities executing maintenance cleansing process 300 should not be interpreted as being limiting with regard to the concepts provided by the instant disclosure.

With this said, maintenance cleansing process 300 commences at task block 302, in which a first, second, third, and fourth operational cleansing cycle and corresponding cycle duration times t₁-t₄ are defined based on the cleansing properties of the corresponding first, second, and third/fourth liquids. As noted above, the first liquid comprises a detergent having an acidic ph level, the second liquid comprises a water softening additive agent, and the third and fourth liquids comprise osmosed water with anti-corrosion additive agents having basic ph levels.

At task block 304, cleansing process 300 performs a pretest to measure liquid quality levels of the liquid returned from the server rack, as detected by the sensors of WQC 110Z. At decision block 306, process 300 determines whether the quality levels of the return liquid are satisfactory and if so, process 300 terminates at block 308. If not, process 300 moves to task block 310, in which the first cleansing cycle is executed to inject the flow of the first liquid containing acidic detergent from the first tank 110A throughout the data processing assemblies 120A-120M of the datacenter rack unit 120, via the liquid cooling loop 123, and return the “dirty” first liquid back to the first tank 110A for the defined first cycle duration time t₁. As noted above, task block 310 entails the timely actuation and control of pump PA, valves V1, V2, and heat exchanger FHEXA throughout duration of the first cycle.

Upon termination of the first cycle, process 300 executes the second cleansing cycle, at task block 312, to inject the flow of the second liquid containing water softening agents throughout the data processing assemblies 120A-120M of the datacenter rack unit 120, via the liquid cooling loop 123, and return the “dirty” second liquid back to the second tank 110B for the defined second cycle duration time. As noted above, task block 312 entails the timely actuation and control of pump PB, valves V3, V4, and heat exchanger FHEXB throughout duration of the second cycle.

At task block 314, after termination of the second cleansing cycle, process 300 executes the third cleansing cycle to inject the flow of third liquid containing treated osmosed water throughout the data processing assemblies 120A-120M of the datacenter rack unit 120, via the liquid cooling loop 123, and return the “dirty” third liquid back to the second tank 110A, for the defined third cycle duration time. As noted above, task block 314 entails the timely actuation and control of pump PC, valves V5, V6, and heat exchanger FHEXC throughout duration of the third cycle.

At task block 316, upon detection that the quality levels of the return liquid, as measured by the sensors of WQC 110Z are not satisfactory, at task block 316, process 300 executes the fourth operational cycle to again inject the flow of treated osmosed water throughout the processing assemblies for the defined fourth cycle duration time to address any such issues.

Moreover, in the event that the quality levels of the return liquid still remain unsatisfactory, in certain implementations, process 300 may return back to task blocks 310 to 316 to repeat the execution of the first to fourth cleansing cycles.

In this manner, maintenance cleansing system 100 and maintenance cleansing process 300 effectively eliminate the buildup of undesirable contaminants as well as reduce reoccurrences of the same throughout liquid cooling configurations of rack-mounted data processing assemblies. Moreover, the cleansing system and process are capable of performing the cleaning cycles while the data processing assemblies are still in operation with no downtime.

While the above-described implementations regarding the cleansing process have been described and shown with reference to particular steps performed in a particular order, it will be understood that these steps may be combined, sub-divided, or re-ordered without departing from the teachings of the present technology. At least some of the steps may be executed in parallel or in series. Accordingly, the order and grouping of the steps is not a limitation of the present technology.

It will be appreciated that at least some of the operations of the process 300 may also be performed by computer programs, which may exist in a variety of forms, both active and inactive. Such as, the computer programs may exist as software program(s) comprised of program instructions in source code, object code, executable code or other formats. Any of the above may be embodied on a computer readable medium, which include storage devices and signals, in compressed or uncompressed form. Representative computer readable storage devices include conventional computer system RAM (random access memory), ROM (read only memory), EPROM (erasable, programmable ROM), EEPROM (electrically erasable, programmable ROM), and magnetic or optical disks or tapes. Representative computer readable signals, whether modulated using a carrier or not, are signals that a computer system hosting or running the computer program may be configured to access, including signals downloaded through the Internet or other networks. Concrete examples of the foregoing include distribution of the programs on a CD ROM or via Internet download. In a sense, the Internet itself, as an abstract entity, is a computer readable medium. The same is true of computer networks in general.

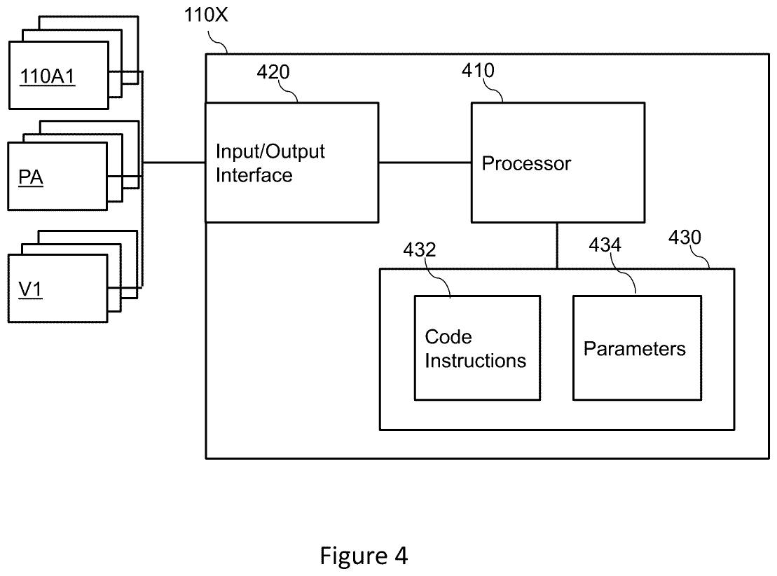

As an example, FIG. 4 is a schematic block diagram of the control module 110X

according to an embodiment of the present technology. The control module 110X comprises a processor or a plurality of cooperating processors (represented as a processor 410 for simplicity), a memory device or a plurality of memory devices (represented as a memory device 430 for simplicity), and an input/output interface 420 allowing the control module 110X to communicate with other components of the mobile cleansing unit 110 and/or other components in remote communication with the mobile cleansing unit 110. The processor 410 is operatively connected to the memory device 430 and to the input/output interface 420. The memory device 430 includes a storage for storing parameters 434. The memory device 430 may comprise a non-transitory computer-readable medium for storing code instructions 432 that are executable by the processor 410 to allow the control module 110X to perform the various tasks allocated to the control module 110X in the process 300.

The control module 110X is operatively connected, via the input/output interface 420, to the fluid control structures 110A1, 110B1, 110C1 and 110D1, the pumps PA, PB, PC, and PD, the valves V1 to V8 and other components of the mobile cleansing unit 110. The control module 110X executes the code instructions 432 stored in the memory device 430 to implement the various above-described functions that may be present in a particular embodiment. FIG. 4 as illustrated represents a non-limiting embodiment in which the control module 110X orchestrates operations of the mobile cleansing unit 110. This particular embodiment is not meant to limit the present disclosure and is provided for illustration purposes.

Modifications and improvements to the above-described implementations of the present technology may become apparent to those skilled in the art. The foregoing description is intended to be exemplary rather than limiting. The scope of the present technology is therefore intended to be limited solely by the scope of the appended claims.

What is claimed is:

1. A maintenance cleansing system for a server rack incorporating liquid-cooled rack-mounted data processing assemblies, comprising:
a cleansing unit comprising:
a first tank containing a volume of a first liquid comprising a detergent having an acidic ph level and fluidly-coupled a first fluid control structure,
a second tank containing a volume of a second liquid comprising softened water or pure water and fluidly-coupled a second fluid control structure, and
a third tank containing a volume of a third liquid comprising treated osmosed water with corrosion inhibitors having a basic ph level and fluidly-coupled a third fluid control structure;
a control module operably-coupled to the first, second, and third fluid control structures and configured to select one of the first, second, or third liquids and define a corresponding first, second, and third operational cleansing cycle and cycle duration time,
a forward fluid coupling section configured to supply the selected liquid to the rack-mounted processing assemblies, and
a return fluid coupling section configured to receive the selected liquid from the rack-mounted processing assemblies;
a rack unit fluid inlet configured to receive the selected fluid from the forward fluid coupling section and distribute the selected liquid throughout each of the rack-mounted processing assemblies for a corresponding cleansing cycle; and
a rack unit fluid outlet configured to receive the distributed selected liquid from each of the rack-mounted processing assemblies, during the corresponding cleansing cycle, and return the distributed selected liquid back to the respective tank.

2. The maintenance cleansing system of claim 1, further comprising a fourth tank containing a volume of a fourth liquid comprising a volume of treated osmosed water with corrosion inhibitors having a basic ph level and fluidly-coupled to a fourth fluid control structure for selection by the control module to establish a corresponding fourth cleansing cycle and cycle duration time.

3. The maintenance cleansing system of claim 1, wherein the cleansing unit further comprises a pump and water quality check (WQS) bench 110Z incorporating water quality sensors to measure liquid quality levels.

4. The maintenance cleansing system of claim 1, wherein each of the first, second, third, and fourth fluid control structures comprises a respective supply liquid channel incorporating at least one pump and at least one solenoid valve for providing proper pressure and flow of the selected liquid into the datacenter rack unit.

5. The maintenance cleansing system of claim 1, wherein each of the first, second, third, and fourth fluid control structures comprises a respective return liquid channel (210A2-201D2) incorporating at least one filter (FA-FD) and at least one heat exchanger (FHEXA-FHEXD) for recleaning and recooling the returned selected liquid.

6. The maintenance cleansing system of claim 1, wherein the cleansing unit is configured to perform the first, second, third, and fourth cleansing cycles while the data processing assemblies remain in operation.

7. The maintenance cleansing system of claim 1, wherein the cleansing unit further comprises a wheel assembly for transportability throughout a datacenter.

8. The maintenance cleansing system of claim 4, wherein the control module defines a first operational cycle configured to:
select the detergent from the first tank;
activate the pump of the first control structure;
open the solenoid flow valve of the first control structure to commence flow of the detergent to be distributed throughout the rack-mounted processing assemblies;
allow the distributional flow of the acidic detergent to continue for a first cycle duration time t₁; and
upon lapsing of the first cycle duration time t₁ and/or upon the WQS 110Z determining that the returning liquid from the processing assemblies satisfies liquid quality levels, shut the solenoid valve and deactivate the pump of the first control structure to terminate the distributional flow of the acidic detergent.

9. The maintenance cleansing system of claim 4, wherein the control module defines a second operational cycle configured to:
select the softened water from the second tank;
activate the pump of the second control structure;
open the solenoid flow valve of the second control structure to commence flow of the softened water to be distributed throughout the rack-mounted processing assemblies;
allow the distributional flow of the softened water to continue for a second cycle duration time t₂; and
upon lapsing of the second cycle duration time t₂ and/or upon the WQS 110Z determining that the returning liquid from the processing assemblies satisfies liquid quality levels, shut the solenoid valve and deactivate the pump of the second control structure to terminate the distributional flow of the softened water.

10. The maintenance cleansing system of claim 4, wherein the control module defines a third operational cycle configured to:
select the treated osmosed water from the third tank;
activate the pump of the third control structure;
open the solenoid flow valve of the third control structure to commence flow of the treated osmosed water to be distributed throughout the rack-mounted processing assemblies;
allow the distributional flow of treated osmosed water to continue for a third cycle duration time t₃; and
upon lapsing of the third cycle duration time t₃ and/or upon the WQS 110Z determining that the returning liquid from the processing assemblies satisfies liquid quality levels, shut the solenoid valve and deactivate the pump of the third control structure to terminate the distributional flow of the treated osmosed water.

11. The maintenance cleansing system of claim 4, wherein the control module defines a fourth operational cycle configured to:
select the treated osmosed water from the fourth tank;
activate the pump of the fourth control structure;
open the solenoid flow valve of the fourth control structure to commence flow of the treated osmosed water to be distributed throughout the rack-mounted processing assemblies;
allow the distributional flow of treated osmosed water to continue for a fourth cycle duration time t₄; and
upon lapsing of the fourth cycle duration time t₄ and/or upon the WQS 110Z determining that the returning liquid from the processing assemblies satisfies liquid quality levels, shut the solenoid valve and deactivate the pump of the fourth control structure to terminate the distributional flow of the treated osmosed water.

12. A maintenance process for cleansing a server rack incorporating liquid-cooled rack-mounted data processing assemblies, comprising:
defining an operational cleansing cycle and duration time, respectively, for a first liquid comprising a detergent having an acidic ph level, a second liquid comprising water softening agents, and a third cleansing liquid comprising treated osmosed water having a basic ph level;
performing a pretest to measure quality levels of liquid returned from the server rack, as detected by water quality sensors;
upon determining that the quality levels of the return liquid are unsatisfactory, executing:
selecting the first liquid and executing the first operational cleansing cycle for the first duration time t₁ to inject and circulate the flow of the first liquid throughout the processing assemblies;
upon termination of the first operational cleansing cycle, selecting the second liquid and executing the second operational cleansing cycle for the second duration time t₂ to inject and circulate the flow of the second liquid throughout the processing assemblies; and
upon termination of the second operational cleansing cycle, selecting the third liquid and executing the third operational cleansing cycle for the third duration time t₃ to inject and circulate the flow of the third liquid throughout the processing assemblies.

13. The maintenance process of claim 12, further comprising defining an operational cleansing cycle and duration time t₄ for a fourth liquid comprising treated osmosed water having a basic ph level and executing the fourth cleansing cycle upon determining that the return liquid from the server rack exhibits unsatisfactory quality levels, as detected by the water quality sensors.

14. The maintenance process of claim 13, wherein, upon determining that, after the fourth cleansing cycle, the return liquid from the server rack continues to exhibit unsatisfactory quality levels, as detected by the water quality sensors, revert back to executing the first to fourth operational cleansing cycles.

15. The maintenance process of claim 1, wherein the liquid quality levels comprise pH level, electrical conductivity, aluminum, copper, and zinc content, and/or aerobic microorganism content.
